(19) United States
(12) Patent Application Publication
(10) Pub. No.: US 2007/0176253 A1
(43) Pub. Date: Aug. 2, 2007

(54) Transistor, memory cell and method of manufacturing a transistor

(76) Inventors: Peng-Fei Wang, Dresden (DE); Rolf Weis, Dresden (DE); Joachim Nuetzel, Dresden (DE); Arnd Scholz, Dresden (DE); Alexander Sieck, Dresden (DE); Sigurd Zehner, Dresden (DE)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/343,812

(22) Filed: Jan. 31, 2006

(51) Int. Cl. H01L 29/00

(52) U.S. Cl. 257/506

(57) ABSTRACT

A transistor which can in particular be used in memory cells of a Dynamic Random Access Memory a memory cell and a method of manufacturing a transistor is disclosed. In one embodiment the transistor is a dual-fin field effect transistor. The transistor includes a first and a second source/drain regions, a channel connecting the first and second source/drain regions, a gate electrode for controlling an electrical current flowing between the first and second source/drain regions. The gate electrode is insulated from the channel by a gate dielectric, wherein the gate electrode is disposed in a gate groove extending in the substrate surface so that the channel comprises two fin-like channel portions extending between the first and second source/drain regions in a cross-sectional view taken perpendicularly to a line connecting the first and the second source/drain regions, the gate electrode delimiting each of the fin-like channel portions at one side thereof.

### FIELD OF THE INVENTION

The invention relates to a transistor, to a memory cell of a DRAM (dynamic random access) memory as well as a method of manufacturing such a transistor.

### BACKGROUND

Memory cells of a dynamic random access memory (DRAM) comprise a storage capacitor for storing an electric charge which represents an information to be stored, and an access transistor for addressing the storage capacitor. The access transistor comprises a first and a second source/drain regions, a conductive channel connecting the first and second source/drain regions as well as a gate electrode controlling an electrical current flowing between the first and second source/drain regions. The transistor usually is formed in a semiconductor substrate, in particular, a silicon substrate. The information stored in the storage capacitor is read out or written in by addressing the access transistor.

There is a lower boundary of the channel length of the access transistor, below which the isolation properties of the access transistor in a non-addressed state are not sufficient. The lower boundary of the effective channel length L_{eff} limits the scalability of planar transistor cells having an access transistor which is horizontally formed with respect to the substrate surface of the semiconductor substrate. Vertical transistor cells offer a possibility of enhancing the channel length while maintaining the surface area necessary for forming the memory cell. In such a vertical transistor cell the source/drain regions of the access transistor as well as the channel region are aligned in a direction perpendicular to the substrate surface.

A concept, in which the effective channel length L_{eff} is enhanced, refers to a recessed channel transistor, as is for example known from the U.S. Pat. No. 5,945,707. In such a transistor, the first and second source/drain regions are arranged in a horizontal plane parallel to the substrate surface. The gate electrode is arranged in a recessed groove, which is disposed between the two source/drain regions of the transistor in the semiconductor substrate. Accordingly, the effective channel length equals to the sum of the distance between the two source/drain regions and the two fold of the depth of the recess groove. The effective channel width W_{eff} corresponds to the minimal structural size F. Further recessed channel transistors are, for example, known from U.S. patent applications Ser. Nos. 2005/0087832 and 2005/0077568.

Another known transistor concept refers to the FinFET. The active area of a FinFET usual has a shape of a fin or a ridge which is formed in a semiconductor substrate between the two source/drain regions. A gate electrode encloses the fin at two or three sides thereof. “A Novel Multi-Channel Field Effect Transistor (MCFET) on Bulk Si for High Performance sub-80 nm Application” by Sung Min Kim et al. IEDM Tech. Dig., pp. 639 to 642, 2004, discloses a double FINFET in which the top side of each of the channels is disposed at the same height as the semiconductor substrate surface. In addition, the gate electrode encloses each of the channels at two sides thereof. A similar transistor is described in “Fully Working High Performance Multi-Channel Field Effect Transistor (McFET) SRAM Cell on Bulk Si substrate Using TiN Single Metal Gate” by Sung Min Kim et al. VLSI Tech. Dig., pp. 196 to 197, 2004.

### SUMMARY

The present invention provides a transistor, a memory cell, and method of manufacturing a transistor. In one embodiment the transistor, is at least partially formed in an active area defined in a semiconductor substrate. The active area is delimited at two sides thereof by isolation trenches filled with an insulating material. The transistor including a first and a second source/drain regions, a channel connecting the first and second source/drain regions, a gate electrode for controlling an electrical current flowing between the first and second source/drain regions, the gate electrode being insulated from the channel by a gate dielectric. The channel includes two fin-like channel portions extending between the first and second source/drain regions, the gate electrode delimiting each of the fin-like channel portions at one side thereof, each of the fin-like channel portions being delimited at the other side thereof by one of the isolation trenches, wherein the width of each of the fin-like channel portions is 5 to 20 nm at the bottom portion thereof, and the height of each of the fin-like channel portions is 30 to 50 nm.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a plan view of a memory device having memory cells according to the present invention.

FIG. 2A illustrates a cross-sectional view of the transistor according to the present invention, wherein the cross-sectional view is taken along the channel direction.

FIG. 2B illustrates a cross-sectional view of the transistor according to the present invention, the cross-sectional view being taken in a direction perpendicular to the direction of the channel.

FIG. 2C illustrates components of the transistor in greater detail.

FIG. 3 illustrates a plan view on the completed memory cell array.

FIG. 4 illustrates a cross-sectional view of storage capacitors before defining a transistor.

FIG. 5 illustrates cross-sectional views of the memory cells after depositing the hard mask layer stack.

FIG. 6 illustrates cross-sectional views of the memory cell after defining a hard mask opening.

FIG. 7 illustrates cross-sectional views of the memory cell after defining a gate groove.

FIG. 8 illustrates cross-sectional views of the memory cell after depositing layers constituting a gate electrode.

FIG. 9 illustrates cross-sectional views of the memory cell after defining the word lines.

FIG. 10 illustrates cross-sectional views of the memory cell after the completion thereof.

FIG. 11A illustrates a cross-sectional view of the transistor according to the first embodiment of the present invention.

FIG. 11B illustrates a cross-sectional view of the transistor according to a second embodiment of the present invention.

FIG. 11C illustrates a cross-sectional view of the transistor according to a third embodiment of the present invention.

FIG. 12 illustrates a cross-sectional view of the transistor according to a fourth embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one embodiment of the present invention, a transistor is at least partially formed in an active area defined in a semiconductor substrate, the active area being delimited at two sides thereof by isolation trenches filled with an insulating material. In particular, the transistor includes a first and a second source/drain regions, a channel connecting the first and second source/drain regions, a gate electrode for controlling an electrical current flowing between the first and second source/drain regions, the gate electrode being insulated from the channel by a gate dielectric, wherein the channel includes two fin-like channel portions extending between the first and second source/drain regions, the gate electrode delimiting each of the fin-like channel portions at one side thereof, each of the fin-like channel portions being delimited at the other side thereof by one of the isolation trenches, wherein the width of each of the fin-like channel portions is 5 to 20 nm at the bottom portion thereof, and the height of each of the fin-like channel portions is 30 to 50 nm.

The invention further provides a transistor, which is at least partially formed in a semiconductor substrate having a surface, the transistor including a first and a second source/drain regions, a channel connecting the first and second source/drain regions, a gate electrode for controlling an electrical current flowing between the first and second source/drain regions, the gate electrode being insulated from the channel by a gate dielectric, wherein the gate electrode is disposed in a gate groove extending in the substrate surface so that the channel comprises two fin-like channel portions extending between the first and second source/drain regions in a cross-sectional view taken perpendicularly to a line connecting the first and the second source/drain regions, the gate electrode delimiting each of the fin-like channel portions at one side thereof.

According to a further embodiment of the present invention a memory cell is at least partially formed in a semiconductor substrate, the memory cell including an access transistor and a storage capacitor, the access transistor being at least partially formed in an active area defined in the semiconductor substrate, the active area being delimited at two sides thereof by isolation trenches filled with an insulating material, the access transistor including a first and a second source/drain regions, a channel connecting the first and second source/drain regions, a gate electrode for controlling an electrical current flowing between the first and second source/drain regions, the gate electrode being insulated from the channel by a gate dielectric, wherein the channel includes two fin-like channel portions extending between the first and second source/drain regions, the gate electrode delimiting each of the fin-like channel portions at one side thereof, each of the fin-like channel portions being delimited at the other side thereof by one of the isolation trenches, wherein the width of each of the fin-like channel portions is 5 to 20 nm at the bottom portion thereof, and the height of each of the fin-like channel portions is 30 to 50 nm, the storage capacitor comprising a storage electrode, a counter electrode, and a capacitor dielectric insulating the storage electrode and the counter electrode, the storage electrode being connected with the first source/drain region of the access transistor.

According to still a further embodiment of the present invention, a method of manufacturing a transistor includes providing a substrate having a surface, providing isolation trenches in the substrate surface, filling the isolation trenches with an insulating material, thereby defining an active area, the active area being delimited at two sides thereof by isolation trenches, providing a first and a second source/drain regions, providing a channel connecting the first and second source/drain regions, providing a gate electrode for controlling an electrical current flowing between the first and second source/drain regions, providing a gate dielectric for insulating the gate electrode from the channel, wherein providing a gate electrode is performed in such a manner that the channel comprises two fin-like channel portions extending between the first and second source/drain regions, the gate electrode delimiting each of the fin-like channel portions at one side thereof, each of the fin-like channel portions being delimited at the other side thereof by one of the isolation trenches and wherein providing a gate electrode is performed in such a manner that the width of each of the fin-like channel portions is 5 to 20 nm at the bottom portion thereof, and the height of each of the fin-like channel portions is 30 to 50 nm.

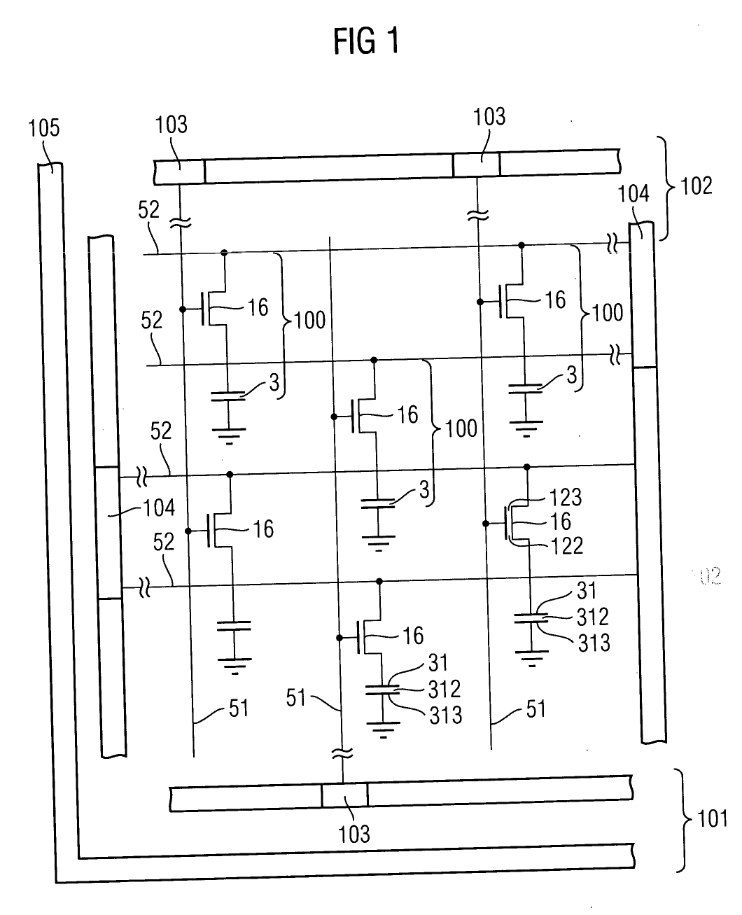

FIG. 1 illustrates a plan view of an exemplary memory device having transistors according to the present invention and, in particular, memory cells according to the present invention. In the central portion of FIG. 1, the memory cell array having memory cells 100 is shown. Each of the memory cells 100 having a storage capacitor 3 and an access transistor 16. The storage capacitor 3 having a storage electrode 31 and a counter electrode 313. The counter electrode 313 is insulated from the storage electrode 31 by a capacitor dielectric 312. The storage capacitor 3 can be implemented in an arbitrary manner. In particular, the storage capacitor 3 can be implemented as a trench capacitor as will be described hereinafter. Nevertheless, the storage capacitor 3 can as well be implemented as a stacked capacitor, wherein the storage electrode 31 as well as the counter electrode 313 are disposed above the semiconductor substrate surface.

The storage electrode 31 is connected with a corresponding one of the first source/drain regions 122 of the access transistors 16. The second source/drain region 123 of the access transistor 16 is connected with a corresponding bit line 52. The conductivity of the channel formed between the first and second source/drain regions 122, 123 is controlled by the gate electrode 171 which is addressed by a corresponding word line 51. In particular, by activating a certain word line, a corresponding voltage is applied to each of the gate electrodes connected with this word line 51. As a consequence, the channel 14 becomes conductive and the charge stored in the storage capacitor is read out via the first and second source/drain regions 122, 123 and the corresponding bit line contact to the corresponding bit line 52.

As is clearly to be understood, the specific layout of the memory cell array is arbitrary. In particular the memory cells 100 can be arranged, for example, in a checkerboard pattern or in any other suitable pattern. The memory device of FIG. 1 further includes a peripheral portion 101. Usually, the peripheral portion 101 includes the core circuitry 102 including word line drivers 103 for addressing the word lines 51 and sense amplifiers 104 for sensing a signal transmitted by the bit lines 52. The core circuitry 102 usually includes other devices and in particular, transistors, for controlling and addressing the individual memory cells 100. The peripheral portion 101 further includes the support portion 105 which usually lies outside the core circuitry. The transistors of the peripheral portion can be arbitrary. In particular, they can be implemented as conventional planar transistors. Nevertheless, they can as well be formed in the manner as will be illustrated in the following.

Stated more concretely, the transistor of the present invention can be applied in arbitrary applications. In particular, it can form part of a memory cell as has been described above; in addition, the transistor can as well be disposed in the peripheral portion of a memory device, or it can be used in arbitrary applications.

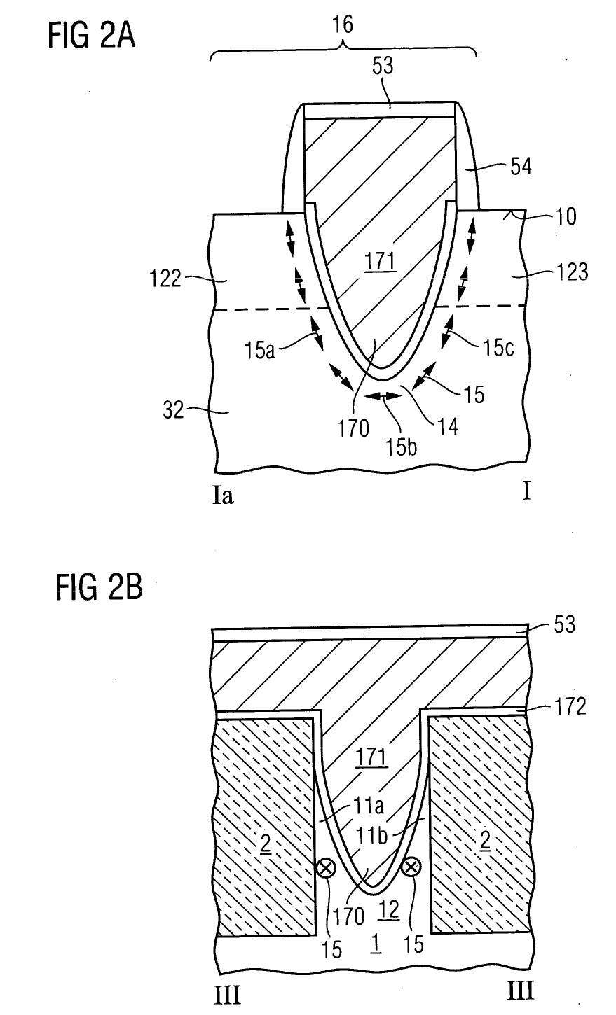

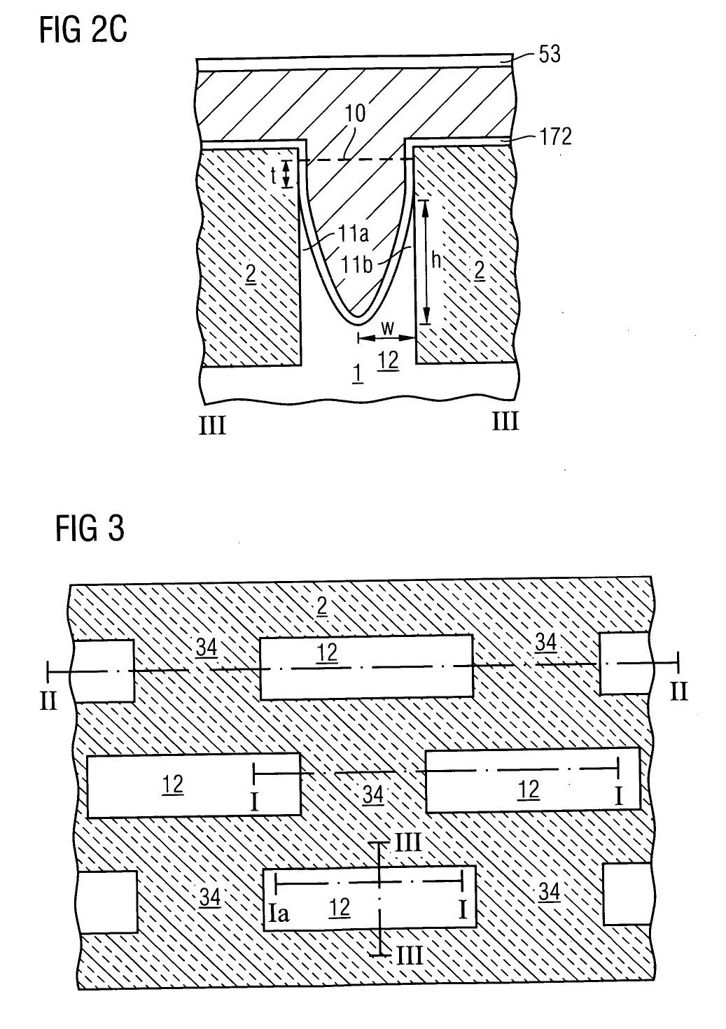

FIG. 2A illustrates a cross-sectional view of the array transistors 16 along a first direction connecting the first and second source/drain regions 122, 123. In particular, the direction, along which the cross-sectional view of FIG. 2A is taken, can be gathered from FIG. 3.

The transistor 16 includes a first and second source/drain regions 122, 123 and a channel 14 connecting the first and second source/drain regions 122, 123. The conductivity of the channel is controlled by the gate electrode 171. The first and second source/drain regions 122, 123 are disposed in the surface region of a semiconductor substrate 1, in particular, a silicon substrate. The gate electrode 171 is formed in a gate groove 170. In particular, the gate groove 170 is etched into the semiconductor substrate. In addition, the gate groove 170 extends to a depth below the lower boundary of the first and second source/drain regions 122, 123. As can be seen from FIG. 2A, a current path 15 of a current flowing in the transistor comprises a first component 15a which extends in a first vertical direction, i.e., downwards, a second component 15b which extends in a horizontal direction, and a third component 15c extending upwards, i.e. in a second vertical direction which is opposite to the first vertical direction.

In addition, FIG. 2B illustrates a cross-sectional view which is taken perpendicular to the direction of the channel. In particular, the cross-sectional view of FIG. 2B is taken between III and III, as can be seen from FIG. 3.

As can be seen from FIG. 2B the transistor of the present invention is implemented as a dual channel FINFET, in which the active area 12 includes two channels or two fin-like portions 11a, 11b. In particular, the transistor 16 is formed in an active area 12 which is defined by etching isolation trenches 2 and filling them with an insulating material, such as SiO₂. Accordingly, the active area 12 is delimited by the two isolation trenches 2 at two lateral sides thereof. The gate groove 170 is etched in the active area so that as a result the channel includes two channel portions which nearly have the shape of triangles. The two channel portions are disposed between each of the isolation trenches 2 and the neighboring gate electrode 171. In more detail, the sidewalls of the fin-like portions 11a, 11b need not necessarily be straight lines. Nevertheless the shape of each of the fin-like portions 11a, 11b is close to a triangle. In addition, the sidewall of the fin-like portion adjacent to the isolation trench 2 intersects the sidewall of the fin-like portion adjacent to the gate groove 170. Accordingly, after forming a gate dielectric and after depositing the gate electrode material, the channel comprises two fin-like channel portions which extend between the first and second source/drain regions, wherein the gate electrode 171 delimits each of the fin-like channel portions 11a, 11b at one side thereof, and wherein each of the fin-like channel portions is delimited at the other side thereof by one of the isolation trenches.

Accordingly, the transistor of the present invention includes a gate electrode which is disposed in a gate groove that is formed in the substrate surface. The gate groove is formed in such a manner that it splits up the channel into two fin-like portions 11a, 11b in a cross-section perpendicular to a line connecting the first and the second source/drain regions 122, 123.

The transistor shown in FIGS. 2A and 2B offers a variety of advantages. In particular, when addressing the gate electrode 171, the fin-like channel portions 11a and 11b can be fully depleted. As a consequence, a potential applied to the gate electrode 171 will immediately influence the charge density in each of the fin-like channel portions 11a, 11b. As a consequence, the transistor has an improved sub-threshold slope in comparison with the conventional transistors. Hence, an improved on-current/off-current ratio is obtained. In addition, as can be seen from FIG. 2B the effective channel width is enlarged so that there is more current flowing.

FIG. 2C illustrates typical dimensions in the transistor of the present invention. In particular, each of the fin-like portions has a width w in the bottom part thereof. In particular, the width w is equal to the distance between the bottom side of the gate electrode 171 and the isolation trenches 2. The width w can be 5 to 20 nm, in particular, 10 to 20 nm. The height h of the fin-like channel portion amounts to the height of the channel portion in which the channel is enclosed by a gate electrode 171 on the one side thereof and by the isolation trench 2 on the other side thereof. Accordingly, the height h corresponds to the distance between the top side of the channel and the bottom side of the gate electrode 171. In particular, the height h of the fin-like channel portion can be 30 to 50 nm, in particular, 40 to 50 nm. In addition, as can be seen from FIG. 2C, the fin-like channel portion 11a, 11b is recessed with respect to the substrate surface 10. As a result, the upper portion of the fin-like channel portion 11a, 11b is disposed beneath the substrate surface 10. In particular, the distance between the substrate surface 10 and the upper portion of the fin-like channel portion 11a, 11b is denoted by t. In particular, t can be up to 50 nm.

FIGS. 3 to 10 illustrate one process of manufacturing a transistor according to an embodiment of the present invention. Starting point of the method of the present invention is an array of completed storage capacitors.

FIG. 3 illustrates a plan view on part of such a capacitor array after forming the storage capacitors and after defining the active areas 12. In particular, the active areas are formed as segments of stripes, two segments of active areas 12 in one row being insulated from each other by the trench top oxide 34 which is formed above a corresponding trench capacitor. Adjacent stripes of active areas 12 of different rows are spaced apart, isolation trenches 2 being disposed between neighboring rows, the isolation trenches being filled with an insulating material. The segments of the active areas 12 are arranged in a checkerboard manner, so that the segments of adjacent rows are arranged in a staggered manner. To be more specific, the segments of adjacent rows are offset by half of the cell pitch, in particular, 2 F. In this respect, F denotes the minimal structural feature size which can be obtained by the lithographic method employed. In particular, F can be 130, 120, 100, 80, 60, 40, 25 nm or even less.

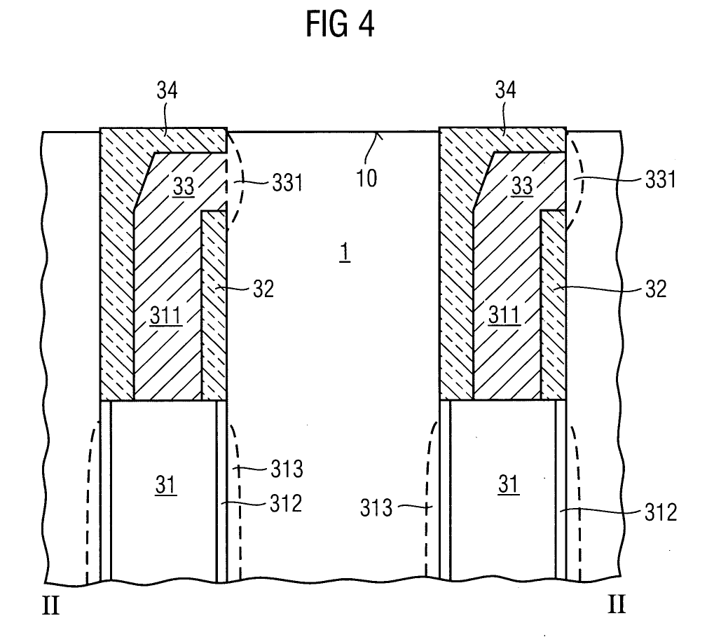

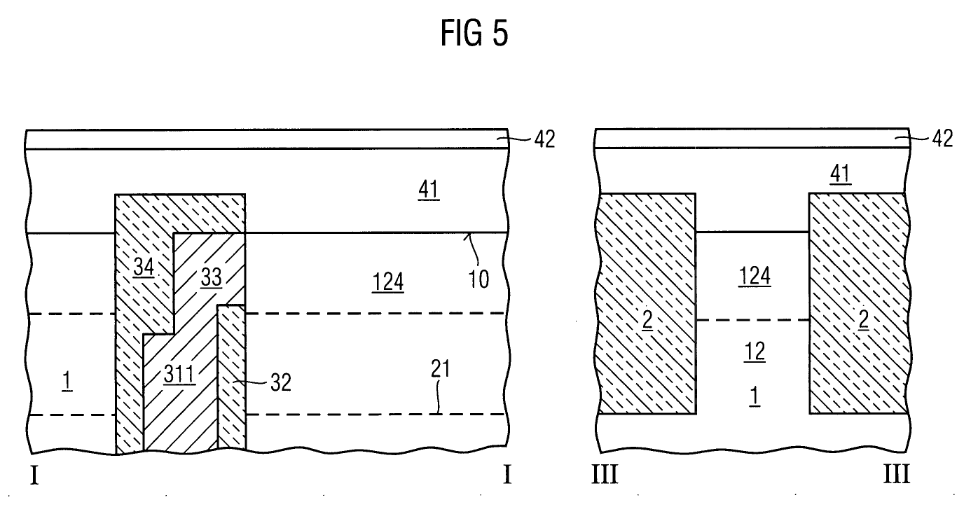

A cross-sectional of the array shown in FIG. 3 between I and I is illustrated in FIG. 4. As can be seen from FIG. 4, trench capacitors 3 are provided so as to extend in the semiconductor substrate 1, in particular, a p-doped silicon substrate. The trench capacitor includes a storage electrode or inner electrode 31, a counter electrode 313, which is implemented as a heavily doped n-portion as well as a capacitor dielectric 312 which is disposed between the inner electrode 31 and the counter electrode 313. The capacitor dielectric 312 can be made of SiO₂, SiON, Al₂O₃ or any other so-called high-k material as is commonly used. In the upper portion of the trench capacitor 3, an isolation collar 32 is provided, as is conventional in the art. A polysilicon filling 311 is provided so as to accomplish an electrical contact between the storage electrode 31 and the buried strap window 33 which is formed above the isolation collar 32. Above the poly-silicon filling 311, a trench top oxide layer 34 is provided. For example, the total thickness of the top oxide layer 34 can be approximately 30 nm, wherein the top oxide layer 34 can project from the substrate surface 10, so that the buried strap window 33 is disposed close to the substrate surface 10. Nevertheless, the top surface of the trench top oxide layer 34 can as well be at the same level as the substrate surface 10.

The formation of the trench capacitor 3 is generally known and the description thereof is omitted for the sake of convenience. In particular, the trench capacitor can include a buried strap so as to accomplish an electrical contact between the inner capacitor electrode 31 and the first source/drain portion of the transistor to be formed. The dopants of the poly-silicon filling 311 diffuse into the substrate portion so as to form the buried strap of the diffusion portion 311. After providing the trench capacitors, isolation trenches 2 for laterally confining the active areas 12 are etched and filled with an insulating material as is common. For example, the isolation trenches 2 can be filled with a first silicon dioxide layer, a silicon nitride liner and a silicon dioxide filling. The isolation trenches 2 can be formed so as to have side walls extending perpendicularly with respect to the substrate surface. Nevertheless, it is as well possible that the isolation trenches 2 have inclined side walls. After defining and filling the isolation trenches, optionally, a doped portion 124 can be provided. In particular, the doped portion 124 is provided by performing an ion implantation process. After defining the gate groove 170 as will be described hereinafter, first and second source/drain regions 122, 123 will be formed of this doped region 124.

After defining the isolation trenches 2, a hard mask layer stack for defining the gate groove 170 is deposited. In particular, first, a carbon hard mask layer 41 having a thickness of approximately 200 nm, followed by an SiON (silicon oxynitride) layer 42 having a thickness of approximately 60 nm is deposited. For example, the carbon hard mask layer can be formed of a carbon film, which may be deposited by physical vapour deposition or chemical vapour deposition. In particular, the carbon film can be made of amorphous carbon, which may optionally comprise hydrogen.

The resulting structure is shown in FIG. 5, wherein the left hand portion of FIG. 5 shows a cross-sectional view between I and I along the channel, and the right hand portion of FIG. 5 illustrates a cross-sectional view perpendicular to the direction of the channel. As can be seen, the hard mask layers 41, 42 are deposited over the whole surface.

In the next process, openings 43 are photolithographically defined in the hard mask layer stack. In particular, a photo resist layer (not shown) is deposited on the surface of the SiON layer 42 and openings are photolithographically defined in the photo resist layer. For example, openings having the shape of stripes can be defined or, alternatively, the openings can be defined using a mask having a dot pattern or a pattern of segments of stripes, so that only a portion of the photo resist layer which directly lies over an active area is opened. Thereafter, taking the patterned photo resist layer as an etching mask, the openings 43 are etched in the SiON hard mask layer 42 as well as in the carbon hard mask layer 41. For example, the SiON hard mask layer 42 can be etched using a CHF₃/CF₄/Ar gas mixture. In addition, the carbon hard mask layer 41 can be etched using a HBr/O₂/N₂ gas mixture. Thereafter, the photo resist layer (not shown) is removed.

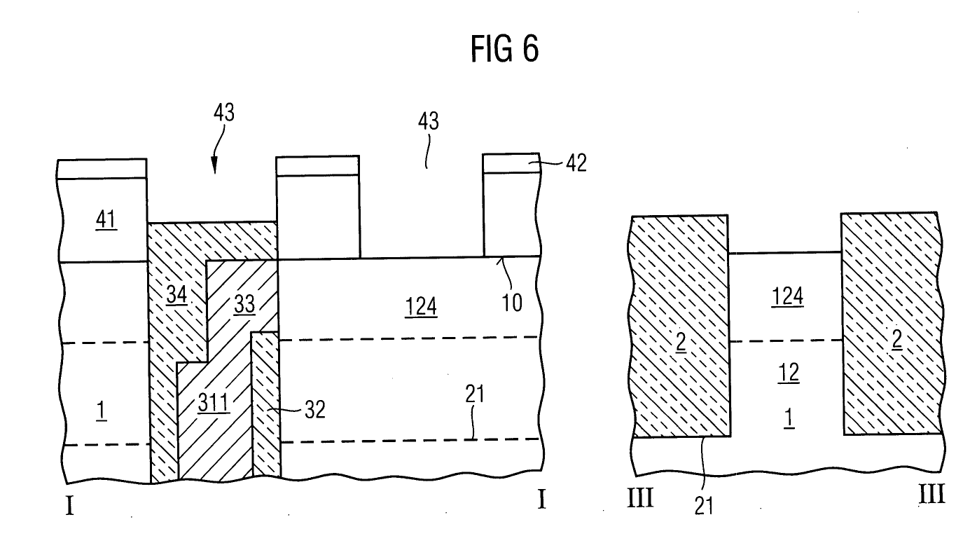

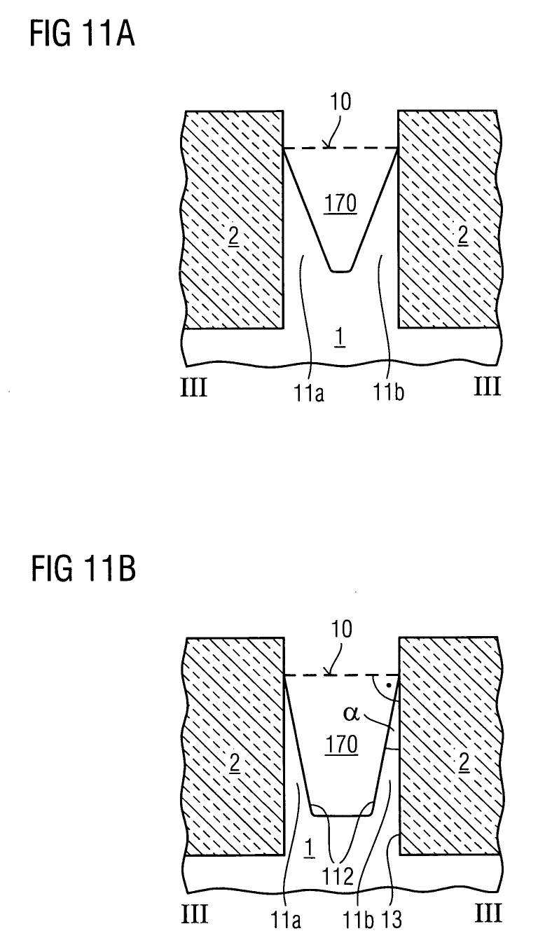

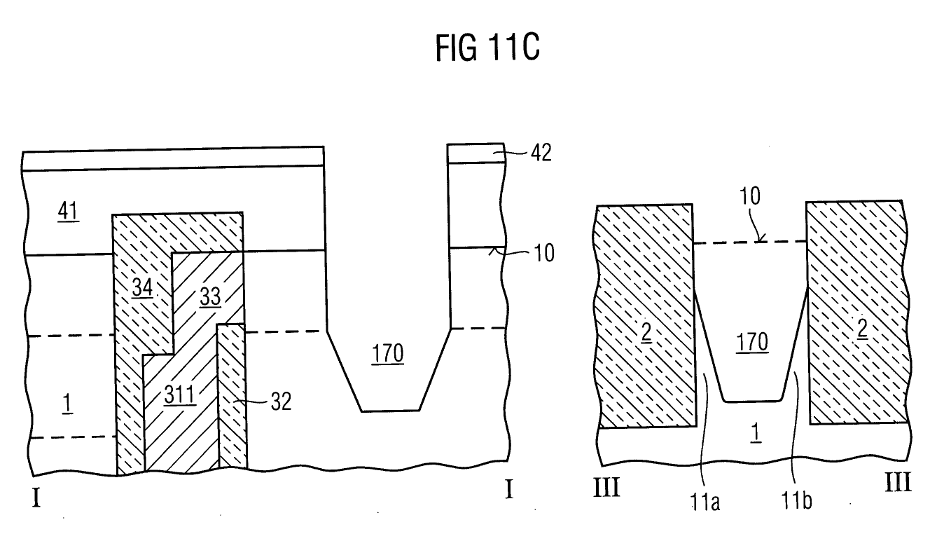

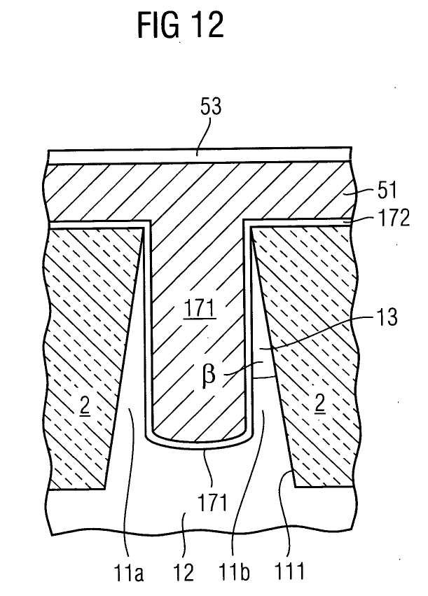

FIG. 6 illustrates a cross-sectional view of the resulting structure, wherein a mask having a lines/spaces pattern has been used for patterning the hard mask layer stack. As is illustrated in the left hand portion of FIG. 6, openings 43 are formed in the hard mask layer stack. In addition, as can be taken from the right hand portion of FIG. 6, the hard mask layers 41, 42 are completely removed from the surface along a direction which is perpendicular with respect of the channel to be formed. Thereafter, taking the defined openings 43 in the hard mask layers as an etching mask, the silicon substrate 1 is etched selectively with respect to the material of the isolation trenches 2. In particular, the gate groove 170 is etched to a depth of 100 to 190 nm. In addition, this etching process is preferably performed as an etching process producing inclined side walls of the gate groove. More specifically, this can be achieved by performing an tapered etching process. In particular, by using a mixture CF₄/HBr at a flow rate of 10 SCCM (cubic centimeters under standard conditions) CF₄ and 100 SCCM HBr, a profile which is similar to the profile shown in FIG. 11B is obtained. By increasing the amount of CF₄ gas, for example to flow rates of 20 SCCM CF₄ and 100 SCCM HBr, the profile illustrated in FIG. 11A is obtained. Finally, by choosing a mixture of HBr and He with added O₂ at a ratio of 70% He and 30% O₂, at a flow rate of 10 SCCM He/O₂ mixture and 100 SCCM HBr, the profile shown in FIG. 11C is obtained, in which the top most portion of the channel is disposed beneath the substrate surface as will be explained later in detail. Generally speaking, by performing an anisotropic etching process of the silicon substrate material with selected ratios of the components of the gas mixture, a desired profile of the channel can be adjusted.

Since the isolation trenches laterally confine the active areas and, in addition, the openings 43 formed in the hard mask layer stack are taken as an etching mask, the dual-fin structure is formed in a self-aligned manner with respect to the active areas 12.

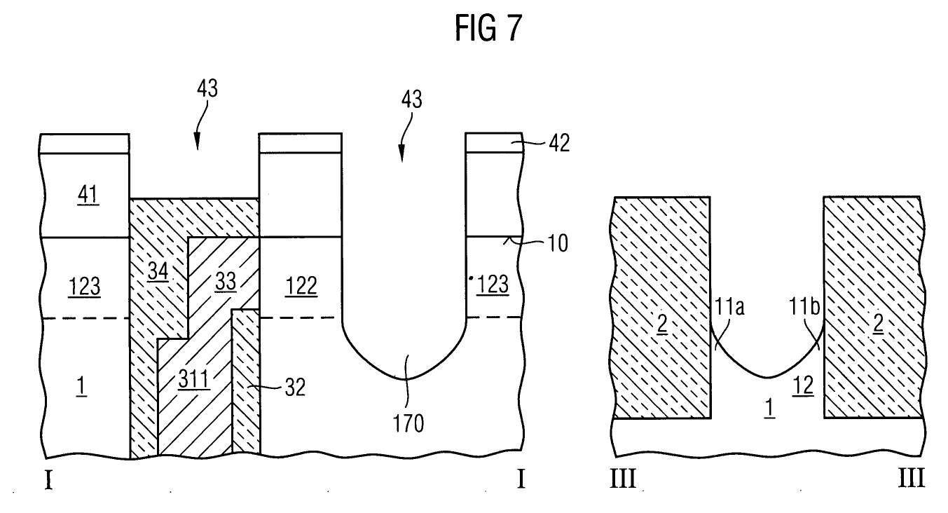

The resulting structure is illustrated in FIG. 7. As can be seen from the left hand portion of FIG. 7, the gate groove 170 is etched in the semiconductor substrate 1. As can in particular be seen from the right hand portion of FIG. 7, two fin-like portions 11a, 11b of the channel are defined. In particular, one side of the fin-like region is adjacent to the isolation trench 2. If the doped portion 124 is provided before etching the gate groove 170 the parameters of the etching process have to be selected in order to make sure that the fin-like portions 11a, 11b are disposed in the undoped substrate portion. Accordingly, the process conditions have to be set, so that first the groove is etched perpendicularly with respect to the substrate surface and is etched so as to provide inclined side walls after reaching the lower boundary of the doped portion 124. Thereafter, the hard mask layer stack is removed.

In the next process, a gate dielectric 172 is provided, for example by performing an oxidation process. Thereafter, the material for forming the gate electrode and, optionally, the word lines is deposited by generally known methods. For example poly-silicon material or any other suitable layer stack comprising, for example, poly-silicon, TiN, WN, can be deposited in order to form the gate electrode. Thereafter, the Si₃N₄ cap layer 53 is deposited.

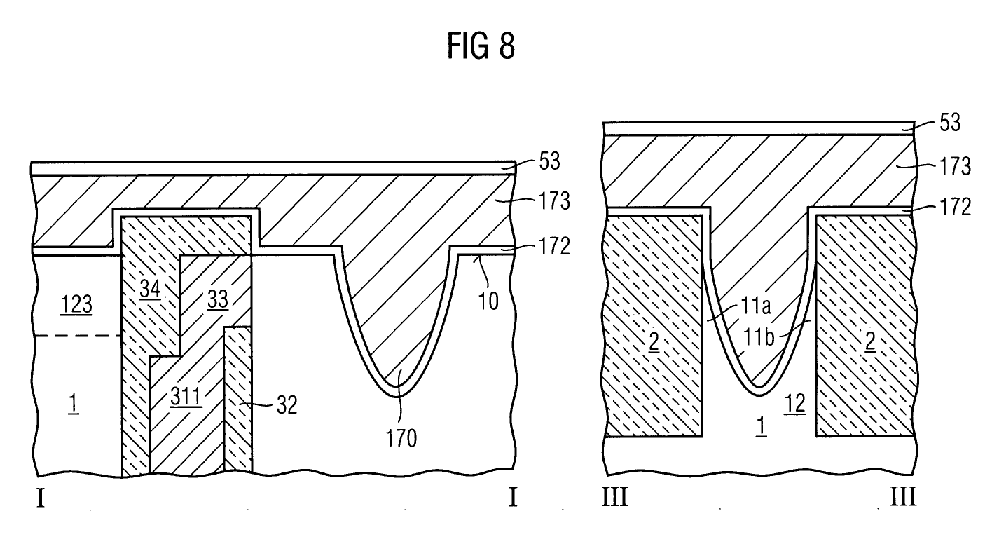

The resulting structure is illustrated in FIG. 8. As can be seen from the left and right hand portion of FIG. 8, now, the whole surface is covered with the gate dielectric layer 172 as well as the material of the gate electrode as well as the Si₃N₄ cap layer 53. In the next process, the layer stack comprising the gate dielectric 172, the gate electrode material 173 as well as the Si₃N₄ cap layer 53 are patterned as is conventional so as to form the word lines 51. Thereafter, a Si₃N₄ spacer 54 is provided by a conventional method, i.e., by conformally depositing a Si₃N₄ layer 54 and performing an anisotropic etching process so as to remove the horizontal portions of the Si₃N₄ layer. In addition, if the doped portions as has been described above have not been provided before the process of forming the gate electrode, now ion implantation processes will be performed so as to provide the first and second source/drain regions 122, 123.

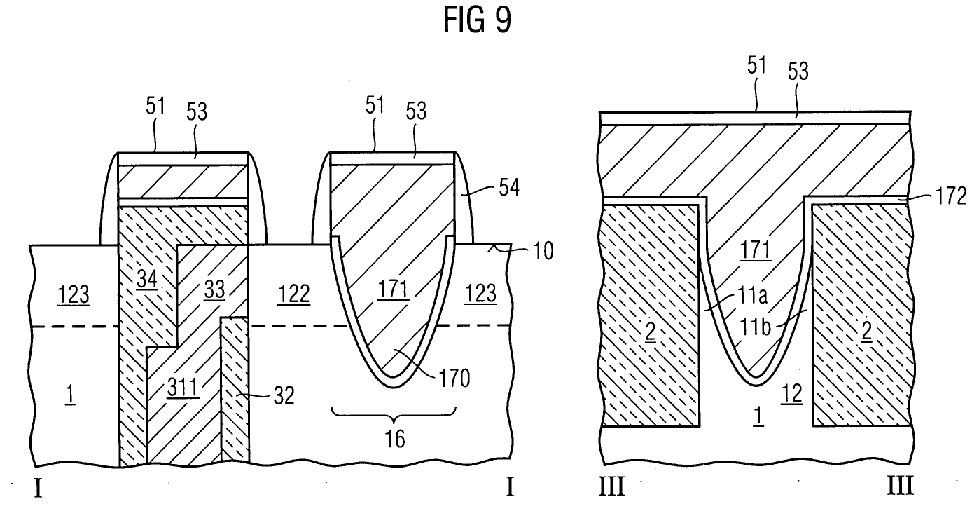

The resulting structure is illustrated in FIG. 9. As can be seen from the left hand portion of FIG. 9, now word lines 51 are formed. In particular, a passing word line is disposed above the trench capacitor and is electrically insulated there from by the trench top oxide layer 34. Moreover, the active word line acts as a gate electrode 171 of the transistor 16 formed by the described process. As can be seen from the right hand portion of FIG. 9, the channel now comprises two fin-like portions 11a, 11b. On one side of the fin-like portions 11a, 11b an isolation trench 2 is disposed, whereas the other side of the fin-like portions 11a, 11b is adjacent to the gate electrode 171. Due to the narrow width of the fin-like portions in the upper portion thereof, the channel can fully depleted in the fin-like portions 11a, 11b. Since the word lines 51 act as a mask during the ion implantation process, the fin-like channel portions 11a, 11b are not doped by this ion implantation process. The memory cell is completed in the conventional manner by providing bit line contacts 57 which are electrically insulated from each other by the BPSG layer 56. Thereafter bit lines 52 are formed by depositing a conductive layer, followed by an insulating layer 55 and, subsequently, patterning the layer stack so that the bit lines finally in direction intersecting the direction of the word lines 51. The bit lines are electrically insulated from each other by a BPSG layer 56.

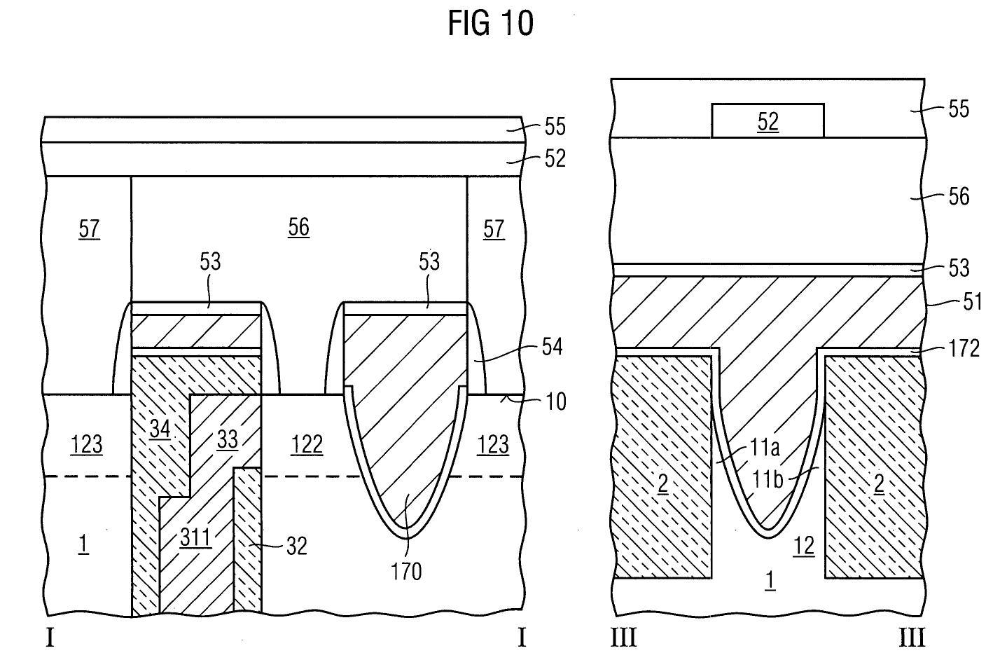

FIG. 10 illustrates a cross-sectional view of the completed memory cell. As can be seen from the left hand portion of FIG. 10 showing a cross-sectional view along the channel direction, the bitlines 52 are connected with the second source/drain regions 123 via bitline contacts 57. As can be seen from the right hand portion showing a cross-sectional view perpendicularly to the channel direction, the word line 51 extends perpendicularly to the channel direction, whereas the bitline 52 extends in the channel direction. Neighboring bit lines are electrically insulated from each other by the BPSG layer 55.

In the etching step which has been described with reference to FIG. 7, by choosing the appropriate process parameters, the profile of the gate groove 170 etched into the substrate 1 can be adjusted. Differently stated, by choosing the process conditions, the cross-sectional shape of the fin-like portions 11a and 11b can be determined. FIGS. 11A to 11C illustrate various profiles of the gate grooves 170 etched into the substrate. For example, as is illustrated in FIG. 11A, the fin-like portions 11a, 11b can extend nearly to the surface 10 of the semiconductor substrate. In this case, the fin-like portions 11a, 11b can be fully depleted when applying an appropriate gate voltage to the gate electrode 171. Nevertheless, the channel length in the upper fin-like portions 11a, 11b corresponds to the channel length of a planar transistor, in which the channel is not recessed. In addition, FIG. 11B illustrates a cross-sectional view of the fin-like portions 11a, 11b, in which the fin-like portions 11a, 11b are narrowed with respect to the structure illustrated in FIG. 11A. Also in the structure illustrated in FIG. 11B, the upper portion of the fin-like portions 11a, 11b is adjacent to the substrate surface 10. FIG. 11B illustrates also the angle α with respect to the normal 13 to the substrate surface. In particular, the angle α defines the angle of the sidewall 112 of the fin-like portion which is adjacent to the gate electrode with respect to the normal 13 to the substrate surface.

As is illustrated in FIG. 11C, the gate groove 170 is etched by first vertically etching the gate groove, and, thereafter, changing the process conditions so as to produce inclined side walls. In this case, the upper edge of the fin-like portions 11a, 11b is disposed beneath the substrate surface 10, so that the effective channel length in the upper portion of the fin-like portions is enlarged. Nevertheless, by adjusting the process conditions for forming the inclined side walls, the shape and, in particular the width of the fin-like portions 11a, 11b can be adjusted.

As has become apparent from the foregoing, by choosing the process parameters, in particular, by combining, for example, an etching process so as to produce vertical side walls with an etching process for producing inclined side walls, any desired profile of the gate groove 170 can be adjusted whereby any desired shape of the fin-like portions 11a, 11b can be set.

Accordingly, the method of forming a transistor according to the present invention preferably comprises a process of selecting the process conditions so as to obtain in a desired shape of the fin-like channel portions 11a, 11b. In particular, the method of forming a transistor can comprise a process of selecting the etching conditions so as to set a predetermined angle α of the sidewall 112 of the fin-like portion 11a, 11b—the sidewall 112 being adjacent to the gate electrode 171—with respect to a normal 13 to the semiconductor substrate surface.

FIG. 12 illustrates a further embodiment of the present invention, wherein the gate groove essentially has vertical side walls whereas the isolation trenches 2 have inclined side walls. Accordingly, the fin-like portions 11a and 11b have a vertical side wall adjacent to the gate electrode 171 and an inclined side wall which is adjacent to the isolation trench. For example, as is illustrated in FIG. 12, an angle β may be formed between the sidewall 111 of the fin-like portion 11b and the normal 13 to the substrate surface, the sidewall 111 of the fin-like portion 11b being adjacent to the isolation trench 2.

As is clearly to be understood, the fin-like portions 11a, 11b can have tapered side walls on either sides thereof. In particular, the boundary between the fin-like portion and the gate electrode can be inclined and, at the same time, the boundary between the fin-like portion and the isolation trench can be inclined. As becomes also apparent, the boundary between the fin-like portion and the isolation trench or the gate electrode 171 need not be a straight line but can have any arbitrary shape.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor, which is at least partially formed in an active area defined in a semiconductor substrate, the active area being delimited at two sides thereof by isolation trenches filled with an insulating material, the transistor comprising:
a first and a second source/drain regions;
a channel connecting the first and second source/drain regions;
a gate electrode for controlling an electrical current flowing between the first and second source/drain regions, the gate electrode being insulated from the channel by a gate dielectric; and
wherein the channel comprises two fin-like channel portions extending between the first and second source/drain regions, the gate electrode delimiting each of the fin-like channel portions at one side thereof, each of the fin-like channel portions being delimited at the other side thereof by one of the isolation trenches.

2. The transistor of claim 1, comprising:
wherein the width of each of the fin-like channel portions is 5 to 20 nm at the bottom portion thereof, and the height of each of the fin-like channel portions is 30 to 50 nm.

3. The transistor of claim 1, wherein the distance between the top portion of the fin-like channel portion and the surface of the substrate is more than 50 nm.

4. The transistor of claim 1, wherein a sidewall of the fin-like channel portion adjacent to one of the isolation trenches extends at an angle β with respect to a normal to the substrate surface, β being less than 90°.

5. The transistor of claim 1, wherein a sidewall of the fin-like channel portion adjacent to the gate electrode extends at an angle α with respect to a normal to the substrate surface, α being less than 90°.

6. A transistor, which is at least partially formed in a semiconductor substrate having a surface, the transistor comprising:
a first and a second source/drain regions;
a channel connecting the first and second source/drain regions;
a gate electrode for controlling an electrical current flowing between the first and second source/drain regions, the gate electrode being insulated from the channel by a gate dielectric; and
wherein the gate electrode is disposed in a gate groove extending in the substrate surface so that the channel comprises two fin-like channel portions extending between the first and second source/drain regions in a cross-sectional view taken perpendicularly to a line connecting the first and the second source/drain regions, the gate electrode delimiting each of the fin-like channel portions at one side thereof.

7. The transistor of claim 6, comprising:
wherein the width of each of the fin-like channel portions is 5 to 20 nm at the bottom portion thereof, and the height of each of the fin-like channel portions is 30 to 50 nm.

8. The transistor of claim 7, wherein the distance between the top portion of the fin-like channel portion and the surface of the substrate is more than 50 nm.

9. The transistor of claim 8, wherein a sidewall of the fin-like channel portion adjacent to one of the isolation trenches extends at an angle β with respect to a normal to the substrate surface, β being less than 90°.

10. The transistor of claim 9, wherein a sidewall of the fin-like channel portion adjacent to the gate electrode extends at an angle α with respect to a normal to the substrate surface, α being less than 90°.

11. A memory cell which is at least partially formed in a semiconductor substrate, the memory cell comprising:
an access transistor and a storage capacitor, the access transistor transistor being at least partially formed in an active area defined in the semiconductor substrate, the active area being delimited at two sides thereof by isolation trenches filled with an insulating material, the access transistor comprising a first and a second source/drain regions;
a channel connecting the first and second source/drain regions;
a gate electrode for controlling an electrical current flowing between the first and second source/drain regions, the gate electrode being insulated from the channel by a gate dielectric; and
wherein the channel comprises two fin-like channel portions extending between the first and second source/drain regions, the gate electrode delimiting each of the fin-like channel portion at one side thereof, each of the fin-like channel portion being delimited at the other side thereof by one of the isolation trenches.

12. The memory cell of claim 11, comprising:
wherein the width of each of the fin-like channel portions is 5 to 20 nm at the bottom portion thereof, and the height of each of the fin-like channel portions is 30 to 50 nm.

13. The memory cell of claim 12, comprising wherein the storage capacitor comprising a storage electrode, a counter electrode, and a capacitor dielectric insulating the storage electrode and the counter electrode, the storage electrode being connected with the first source/drain region of the access transistor.

14. The memory cell according to claim 13, wherein the storage capacitor is implemented as a trench capacitor, wherein the storage electrode, the capacitor dielectric and the counter electrode are disposed in a trench extending in the substrate.

15. The memory cell according to claim 13, wherein the storage capacitor is implemented as a stacked capacitor, wherein the storage electrode, the capacitor dielectric and the counter electrode are disposed above the semiconductor substrate surface.

16. The memory cell according to claim 13, wherein the memory cell is a dynamic random access memory cell.

17. A method of manufacturing a transistor, comprising the steps of:
providing a substrate having a surface;
providing isolation trenches in the substrate surface;
filling the isolation trenches with an insulating material, thereby defining an active area, the active area being delimited at two sides thereof by isolation trenches;
providing a first and a second source/drain regions,
providing a channel connecting the first and second source/drain regions,
providing a gate electrode for controlling an electrical current flowing between the first and second source/drain regions;
providing a gate dielectric for insulating the gate electrode from the channel;
wherein providing a gate electrode is performed in such a manner that the channel comprises two fin-like channel portions extending between the first and second source/drain regions, the gate electrode delimiting each of the fin-like channel portions at one side thereof, each of the fin-like channel portions being delimited at the other side thereof by one of the isolation trenches.

18. The method according to claim 17, further comprising:
wherein providing a gate electrode is performed in such a manner that the width of each of the fin-like channel portions is 5 to 20 nm at the bottom portion thereof, and the height of each of the fin-like channel portions is 30 to 50 nm.

19. The method of claim 18, wherein providing a gate electrode comprises etching a gate groove in the semiconductor substrate, wherein etching the gate groove is performed in such a manner that two fin-like portions are formed in a cross-section perpendicular to a line connecting the first and the second source/drain regions.

20. The method of claim 19, wherein etching a gate groove comprises a tapered etching process.

21. The method of claim 18, wherein etching a gate groove comprises a first process of etching a gate groove having vertical sidewalls and a second process which is a tapered etching process.

22. The method of claim 20, wherein the method comprises:
selecting the etching conditions so as to set a predetermined etching angle of the sidewalls of the gate groove.

23. A memory cell which is at least partially formed in a semiconductor substrate, the memory cell comprising:
means for providing an access transistor and a storage capacitor, the access transistor means being at least partially formed in an active area defined in the semiconductor substrate, the active area being delimited at two sides thereof by isolation trenches filled with an insulating material, the access transistor means comprising a first and a second source/drain regions;
means for providing a channel connecting the first and second source/drain regions;
a gate electrode for controlling an electrical current flowing between the first and second source/drain regions, the gate electrode being insulated from the channel by a gate dielectric; and
wherein the channel comprises two fin-like channel portions extending between the first and second source/drain regions, the gate electrode delimiting each of the fin-like channel portion at one side thereof, each of the fin-like channel portion being delimited at the other side thereof by one of the isolation trenches.
